(19) United States
(12) Patent Application Publication
(10) Pub. No.: US 2011/0174664 A1
(43) Pub. Date: Jul. 21, 2011

(54) COLORED DEVICE CASING AND SURFACE-TREATING METHOD FOR FABRICATING SAME

(75) Inventors: GA-LANE CHEN, Santa Clara, CA (US); CHAO-TSANG WEI, Tu-Cheng (TW); CHUNG-PEI WANG, Tu-Cheng (TW); CHING-CHOU CHANG, Tu-Cheng (TW); SHIH-CHE CHIEN, Tu-Cheng (TW); WEI-CHENG LING, Tu-Cheng (TW); CHIA-YING WU, Tu-Cheng (TW); HSIN-CHIN HUNG, Tu-Cheng (TW); MING-YANG LIAO, Tu-Cheng (TW); TAI-SHENG TSAI, Tu-Cheng (TW); CHIEN-HAO HUANG, Tu-Cheng (TW)

(73) Assignee: HON HAI PRECISION INDUSTRY CO., LTD., Tu-Cheng (TW)

(21) Appl. No.: 12/839,359

(22) Filed: Jul. 19, 2010

(30) Foreign Application Priority Data
Jan. 19, 2010 (TW) 99101309

(51) Int. Cl. B65D 79/00; C23C 14/34; C23C 16/00; C23C 16/44; C23C 16/06

(52) U.S. Cl. 206/524.3; 204/192.1; 427/248.1; 427/255.11; 427/250; 427/255.5

(57) ABSTRACT

A colored device casing includes a base, a color layer and a bonding layer. The base has at least one smooth region. The bonding layer is positioned between the base and the color layer and bonds the base and the color layer together. The color layer includes at least one metal layer. Portion of the color layer corresponding to and located over the smooth region has a value of L* in a range from about 81.59 to about 83.59, a value of a* in a range from about −0.55 to about 0.45 and a value of b* in a range from about −0.60 to about 0.40 according to the Commission Internationale del'Eclairage LAB system. A surface-treating method for fabricating the colored casing is also provided.

### CROSS-REFERENCE TO RELATED APPLICATIONS

This application is related to co-pending U.S. Patent Applications (Attorney Docket Nos. US32560, US32592, US32593, US32594, US32595, US32596, US32597, US32598, US32599, US32600, US32601, US32602, US32603, US32604, US32605 and US32606), all entitled “COLORED DEVICE CASING AND SURFACE-TREATING METHOD FOR FABRICATING SAME”, invented by Chen et al. Such applications have the same inventors and assignee as the present application.

### BACKGROUND

1. Technical Field

The present disclosure generally relates to device casings, and particularly, to a casing colored by physical vapor deposition (PVD).

2. Description of Related Art

Colored device casings are often formed by injection of colored plastic or spraying coating on a surface of a casing. However, neither method can provide an attractive metal texture. Furthermore, metal coating technology is complicated and difficult to control, so only a few colors are available for metal casings.

Therefore, it is desirable to provide a casing and a method for fabricating the casing which can overcome the described limitations.

### BRIEF DESCRIPTION OF THE DRAWINGS

Many aspects of the disclosure can be better understood with reference to the drawings. The components in the drawings are not necessarily drawn to scale, the emphasis instead being placed upon clearly illustrating the principles of the present colored device casing and method for fabricating the casing. Moreover, in the drawings, like reference numerals designate corresponding parts throughout various views.

FIG. 1 is a schematic view of a mobile phone with a colored device casing according to an embodiment of the present disclosure.

FIG. 2 is a partial, cross-sectional view of the colored device casing shown in FIG. 1, showing, inter alia, a color layer.

FIG. 3 is a schematic diagram illustrating the L* value of the color layer shown in FIG. 2 according to the Commission Internationale del'Eclairage (CIE, International Commission on Illumination) LAB system.

FIG. 4 is a schematic diagram illustrating the a* value and the b* value of the color layer shown in FIG. 2 according to the CIE LAB system.

FIG. 5 is a flowchart illustrating an exemplary surface-treating method for fabricating a colored device casing, such as, for example, that of FIG. 1.

### DETAILED DESCRIPTION

Embodiments of the disclosure will now be described in detail with reference to the accompanying drawings.

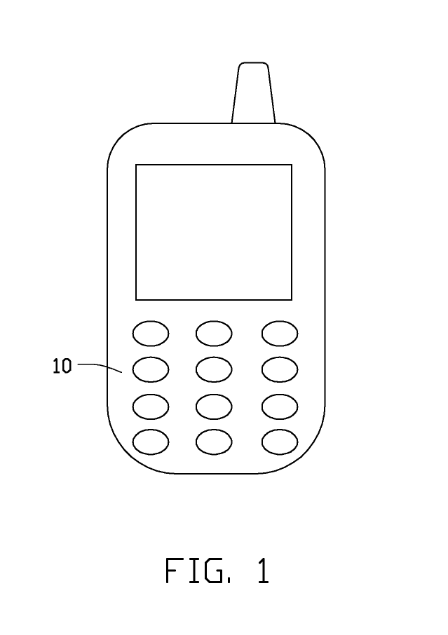

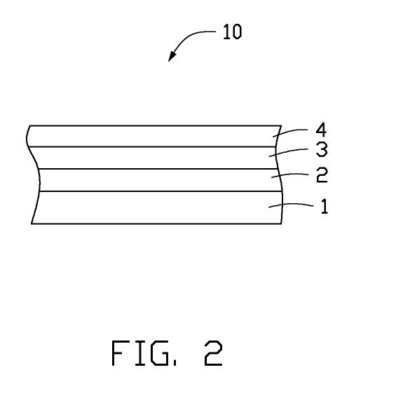

Referring to FIG. 1 and FIG. 2, an embodiment of the present disclosure provides a colored device casing 10 including a base 1, a bonding layer 2, a color layer 3 and an optional coating layer 4. The colored device casing 10 in the illustrating embodiment is a casing of a mobile phone, but is not limited thereto. The bonding layer 2 is located on and covers the base 1; the color layer 3 is located on and covers the bonding layer 2; and the coating layer 4 is located on and covers the color layer 3.

The base 1 can be metal such as steel, or can be ceramic or glass. The base 1 includes at least one surface to be coated, which includes at least one smooth region. The smooth region is also referred to as a high-gloss or a mirror-like region. It is noted that the base 1 may include many surfaces to be coated, and each surface includes many different surface conditions. For example, the base 1 may include both a high-gloss region and a matte region.

The bonding layer 2 is formed between the base 1 and the color layer 3 for connection therebetween. Thus, the bonding layer 2 can include any material providing proper adhesion, such as chromium nitride (CrN).

The color layer 3 is configured to provide desired color, and includes one or more metal layers. In one embodiment, the color layer 3 includes a layer of an alloy of chromium (Cr).

The coating layer 4 can include any appropriate material for protection, such material providing pollution resistance, electrical insulation, moisture insulation, or mechanical hardness.

The part of the colored device casing 10 including the base 1, the bonding layer 2 and the color layer 3 (i.e. excluding the coating layer 4) may exhibit a Vickers hardness equaling or exceeding 500 HV.

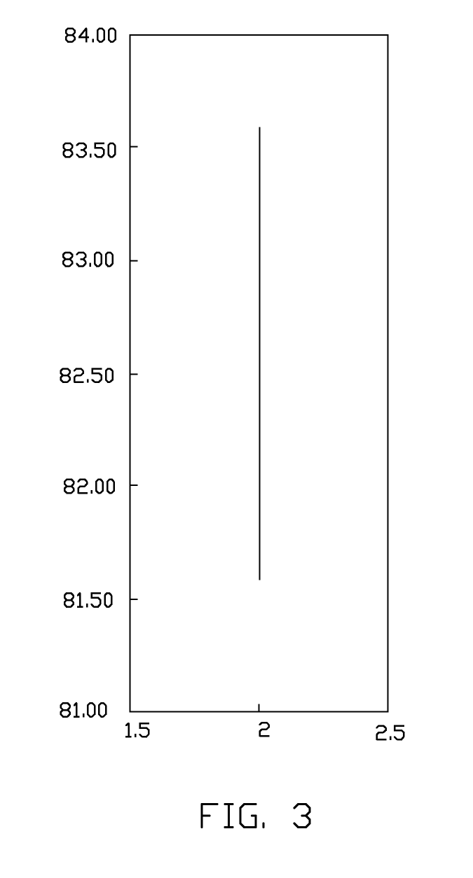

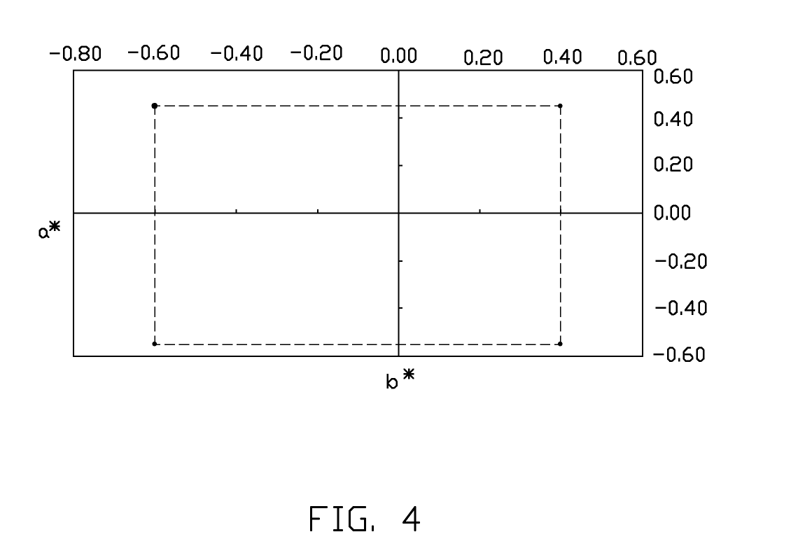

Referring to FIG. 3 and FIG. 4, portion of the color layer 3 corresponding to and located over the smooth region of the base 1 has a value of L* between about 81.59 and about 83.59, a value of a* between about −0.55 and about 0.45 and a value of b* between about −0.60 and about 0.40 according to the Commission Internationale del'Eclairage (CIE) LAB system.

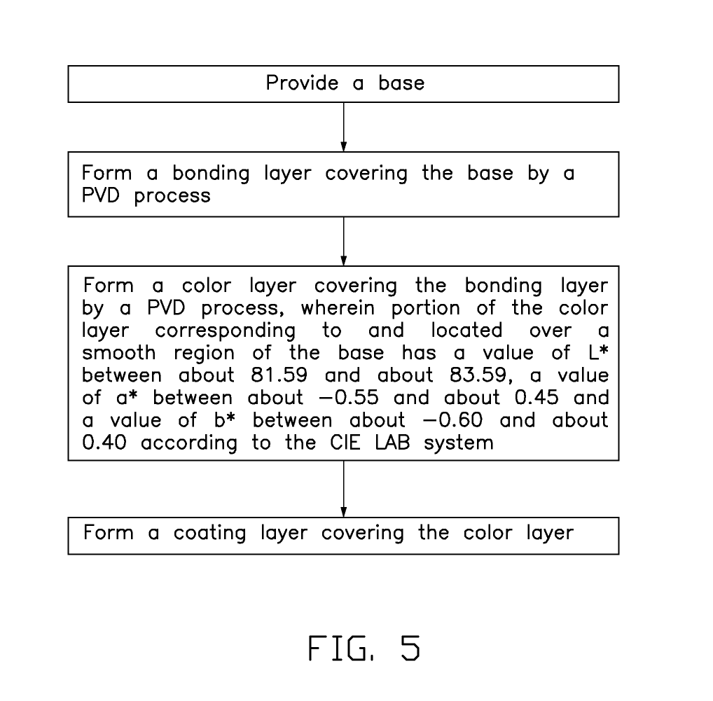

Referring also to FIG. 5, this shows an exemplary surface-treating method for fabricating a colored device casing such as, only for exemplary purpose, the colored device casing 10 of FIGS. 1 and 2. In the method, first, a base 1 is provided. The base 1 may undergo certain surface-treatments in advance as required. For instance, a pre-cleaning step may be carried out on the base 1, or the roughness of the base 1 may be enhanced to better support a subsequently formed bonding layer 2.

Subsequently, a bonding layer 2 is formed on a predetermined surface or region of the base 1. The bonding layer 2 may be formed by PVD, especially PVD sputtering. In one embodiment, argon plasma is excited at a flow rate from 27 to 33 standard cubic centimeters per minute (sccm) by a radio frequency (RF) generator to bombard a chromium target, and nitrogen gas is supplied at a flow rate from 400 to 600 sccm. As a result, chromium vapor is generated and combines with the nitrogen gas, and chromium nitride is obtained and deposits on the base 1.

Thereafter, a color layer 3 is formed on the bonding layer 2. This may include sputtering PVD with argon plasma excited by power supplies to bombard a chromium target In one embodiment, the power bombarding the chromium target is in a range from 18 to 22 kilowatts (kW), the bias voltage is in a range from 216 to 264 volts (V), the process temperature is in a range from 88.2° C. to 107.8° C., the process time is in a range from 9 to 11 minutes, and the process pressure is in a range from 3.6 to 4.4 millitorr (mtorr). The power bombarding the chromium target may be supplied by two power supplies, such as two RF generators or two medium frequency (MF) generators. The base 1 revolves around an axis outside the base 1 at 1.8 to 2.2 revolutions per minute (rpm), and rotates around its own axis at 7.2 to 8.8 rpm. This PVD process provides argon gas in a range from 27 to 33 sccm and nitrogen gas in a range from 54 to 66 sccm.

Accordingly, the colored device casing 10 of the present disclosure provides a desired color and metal texture. The chromaticity coordinate (L*, a*, b*) of the portion of the color layer 3 corresponding to and located over the smooth region of the base 1 is in the range from (about 81.59 to about 83.59, about −0.55 to about 0.45, about −0.60 to about 0.40) according to the CIE LAB system.

Furthermore, a coating layer 4 can be optionally formed on the color layer 3, according to any of various suitable techniques known in the art.

The colored device casing 10 of the present disclosure can be applied to any suitable object or device, such as a notebook or a personal digital assistant (PDA). For example, a mobile phone including the colored device casing 10 shown in FIG. 1 exhibits color and metal texture as described above, and thus provides an enhanced appearance.

It is to be understood, however, that even though numerous characteristics and advantages of various embodiments have been set forth in the foregoing description, together with details of the structures and functions of the embodiments, the disclosure is illustrative only; and that changes may be made in detail, especially in matters of arrangement of parts within the principles of the invention to the full extent indicated by the broad general meaning of the terms in which the appended claims are expressed.

What is claimed is:

1. A colored device casing, comprising:
a base, comprising a surface defining at least one smooth region;
a color layer located over the smooth region of the base, the color layer comprising chromium, wherein the color layer comprises a value for L* in a range from about 81.59 to about 83.59, a value for a* in a range from about −0.55 to about 0.45 and a value for b* in a range from about −0.60 to about 0.40 according to the Commission Internationale del'Eclairage, (CIE) LAB system; and
a bonding layer located between the base and the color layer providing adhesion therebetween.

2. The colored device casing of claim 1, wherein the base is metal, glass or ceramic.

3. The colored device casing of claim 1, wherein the bonding layer comprises chromium nitride.

4. The colored device casing of claim 1, wherein the color layer comprises a layer of an alloy of chromium, and is formed by utilizing a chromium target in a PVD process.

5. The colored device casing of claim 1, wherein a Vickers hardness of the colored device casing equals or exceeds 500 HV.

6. The colored device casing of claim 1, further comprising a coating layer located over the color layer.

7. A surface-treating method for fabricating a colored device casing, the method comprising:
providing a base;
forming a bonding layer covering the base; and
forming a color layer covering the bonding layer by a physical vapor deposition (PVD) process, wherein the color layer comprises a value for L* in a range from about 81.59 to about 83.59, a value for a* in a range from about −0.55 to about 0.45 and a value for b* in a range from about −0.60 to about 0.40 according to the Commission Internationale del'Eclairage, (CIE) LAB system.

8. The method of claim 7, wherein the base is metal, glass or ceramic.

9. The method of claim 7, wherein the color layer comprises a layer of an alloy of chromium.

10. The method of claim 9, wherein the color layer is formed by bombarding a chromium target in the PVD process, the power bombarding the chromium target is in a range from 1.8 to 2.2 kilowatts (kW).

11. The method of claim 7, wherein a bias voltage of the PVD process is from 216 to 264 volts (V).

12. The method of claim 7, wherein a process temperature of the PVD process is from 88.2° C. to 107.8° C.

13. The method of claim 7, wherein the PVD process lasts from 9 to 11 minutes.

14. The method of claim 7, wherein a process pressure of the PVD process is from 3.6 to 4.4 mtorr.

15. The method of claim 7, wherein the PVD process comprises providing argon gas at 27 to 33 standard cubic centimeters per minute (sccm).

16. The method of claim 7, wherein the PVD process comprises providing nitrogen gas at 54 to 66 sccm.

17. The method of claim 7, wherein the base revolves around an axis outside the base at 1.8 to 2.2 revolutions per minute (rpm) in the PVD process.

18. The method of claim 7, wherein the base rotates its own axis[0] at 7.2 to 8.8 rpm in the PVD process.

19. The method of claim 7, wherein the bonding layer is comprised of chromium nitride.

20. The method of claim 7, further comprising forming a coating layer on the color layer.
